(19) United States
(12) Patent Application Publication
(10) Pub. No.: US 2026/0282365 A1
(43) Pub. Date: Sep. 17, 2026

(54) SEMICONDUCTOR DEVICE AND METHOD FOR MANUFACTURING THE SAME

(71) Applicant: MACRONIX INTERNATIONAL CO., LTD., Hsinchu (TW)

(72) Inventors: Chih-Chieh LIN, Pingtung Country (TW); Pei-Ying DU, Hsinchu County (TW)

(21) Appl. No.: 19/080,993

(22) Filed: Mar. 17, 2025

(51) Int. Cl. H10B 43/35; H10D 30/01; H10D 30/69; H10D 62/10; H10D 62/60; H10D 64/01; H10D 64/23; H10D 64/27; H10D 64/68

(52) U.S. Cl. CPC H10B 43/35; H10D 30/0413; H10D 30/696; H10D 62/102; H10D 62/60; H10D 64/037; H10D 64/258; H10D 64/516; H10D 64/685; H10D 64/693

(57) ABSTRACT

A semiconductor device is provided. The semiconductor device includes a substrate, a first well, two first source/drain regions, a first gate dielectric layer and a first gate. The first well is disposed in the substrate. The two first source/drain regions are disposed in the first well and are separated from each other. The first gate dielectric layer is disposed on the substrate. The first gate dielectric layer is a multi-layered structure. The first gate is disposed on the first gate dielectric layer. At least a portion of the first gate dielectric layer covers the two source/drain regions.

### BACKGROUND OF THE INVENTION

### Field of the Invention

The invention relates in general to a semiconductor device and a method for manufacturing the same, and more particularly to a memory device and a method for manufacturing the same.

### Description of the Related Art

In recent years, the market demand for semiconductor devices has been increasing, and the demand for memory devices is also quite significant. Generally speaking, the endurance of a memory device is a very important consideration. The endurance of a memory device indicates the ability of the memory device to withstand repeated read and write operations. Each write and erase operation is called a cycle. If the endurance of the memory device is poor, the reliability of the data will deteriorate, errors may occur after repeated writing and erasing operations, resulting in data damage or loss, and the service life of the memory device will be shortened, thereby increasing costs.

Therefore, there is still an urgent need to develop a memory device that has good endurance.

### SUMMARY OF THE INVENTION

The invention is directed to improving the endurance of a semiconductor device. For example, the present invention provides a semiconductor device in which at least a portion of the first gate dielectric layer covers two first source/drain regions, so that the first gate dielectric layer of the semiconductor device has good structural characteristics and has good endurance in the operation of the memory. It can also extend the service life of the semiconductor device and reduce the cost.

According to some embodiments, the present invention provides a semiconductor structure. The semiconductor device includes a substrate, a first well, two first source/drain regions, a first gate dielectric layer and a first gate. The first well is disposed in the substrate. The two first source/drain regions are disposed in the first well and are separated from each other. The first gate dielectric layer is disposed on the substrate. The first gate dielectric layer is a multi-layered structure. The first gate is disposed on the first gate dielectric layer. At least a portion of the first gate dielectric layer covers the two source/drain regions.

According to some embodiments, the present invention provides a method for manufacturing a semiconductor structure. The method includes the following steps. Provide a substrate. Form a first well. Form two first source/drain regions. Form a first gate dielectric layer. Form a first gate. The first well is disposed in the substrate. The two first source/drain regions are disposed in the first well and are separated from each other. The first gate dielectric layer is disposed on the substrate. The first gate dielectric layer is a multi-layered structure. The first gate is disposed on the first gate dielectric layer. At least a portion of the first gate dielectric layer covers the two source/drain regions.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A is a schematic diagram of a semiconductor device according to an embodiment of the present invention.

FIG. 1B shows a schematic diagram of a semiconductor device according to a comparative example of the present invention.

FIG. 1C shows a schematic diagram of programming the semiconductor device in FIG. 1B.

FIG. 1D shows a schematic diagram of erasing the semiconductor device in FIG. 1B.

FIG. 2A is a schematic diagram of a semiconductor device according to an embodiment of the present invention.

FIG. 2B is a schematic diagram of a semiconductor device according to a further embodiment of the present invention.

FIG. 3A is a schematic diagram of a semiconductor device according to an embodiment of the present invention.

FIG. 3B shows a schematic diagram of a semiconductor device according to a further embodiment of the present invention.

FIG. 4A is a schematic diagram of a semiconductor device according to an embodiment of the present invention.

FIG. 4B is a schematic diagram of a semiconductor device according to a further embodiment of the present invention.

FIG. 5A is a schematic diagram of a semiconductor device according to an embodiment of the present invention.

FIG. 5B is a schematic diagram of a semiconductor device according to a further embodiment of the present invention.

FIG. 6A is a partial cross-sectional view of a semiconductor device according to an embodiment of the present invention.

FIG. 6B is an equivalent circuit diagram of the semiconductor device of FIG. 6A.

### DETAILED DESCRIPTION OF THE INVENTION

Various embodiments will be described in more detail below with reference to the accompanying drawings. The narrative content and diagrams are provided for illustration only and are not intended to be limiting. For clarity, some elements and/or symbols may be omitted in some drawings. In addition, elements in the drawings may not be drawn to actual scale. It is contemplated that elements and features in one embodiment can be advantageously incorporated into another embodiment without further description.

The semiconductor device of the present invention can be applied to BE-SONOS (Bandgap Engineered SONOS) memory, but the present invention is not limited thereto.

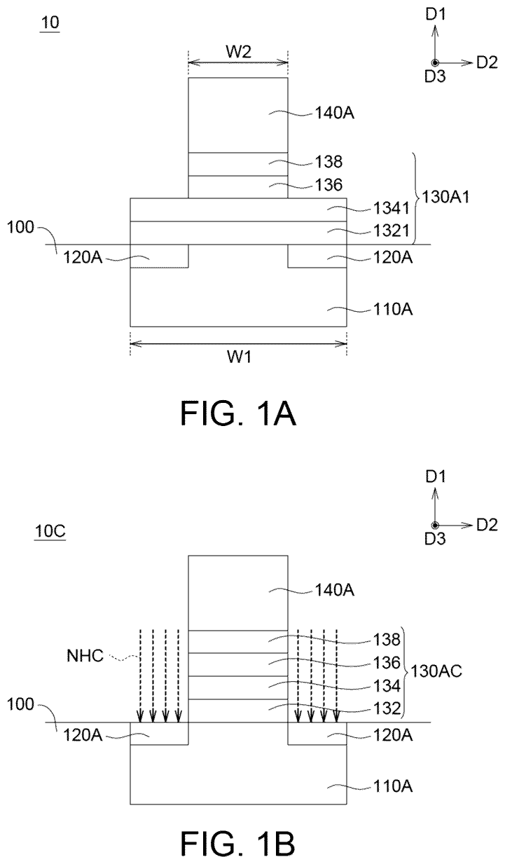

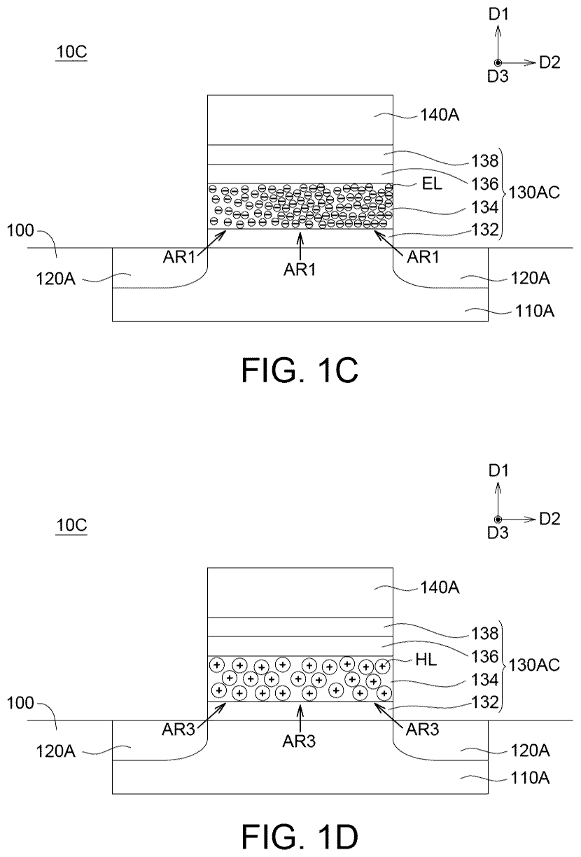

FIG. 1A is a schematic diagram of a semiconductor device 10 according to an embodiment of the present invention.

Referring to FIG. 1A, the semiconductor device 10 includes a substrate 100, a first well 110A, two first source/drain regions 120A, a first gate dielectric layer 130A1 and a first gate 140A. The first well 110A is disposed in the substrate 100. The first source/drain regions 120A are disposed in the first well 110A and are separated from each other. The first gate dielectric layer 130A1 is disposed on the substrate 100. The first gate dielectric layer 130A1 is a multi-layered structure, and the multi-layered structure includes one or more nitride layers and one or more oxide layers. The first gate 140A is disposed on the first gate dielectric layer 130A1, and at least a portion of the first gate dielectric layer 130A1 covers the two first source/drain regions 120A.

Since at least a portion of the first gate dielectric layer 130A1 covers the two first source/drain regions 120A, the etching process of completely removing the first gate dielectric layer 130A1 from above the first source/drain regions 120A (i.e., the etching process NHC described below) can be skipped, making it less likely that the sidewalls of the first gate dielectric layer 130A1 will be damaged by the etching process and/or the cleaning process. Therefore, compared with the comparative example in which the first gate dielectric layer does not cover the two first source/drain regions 120A (as shown in FIG. 1B), the sidewalls of the first gate dielectric layer 130A1 of the semiconductor device 10 have better structural characteristics (less prone to have defects) and can provide good endurance in memory operation (detailed below).

In some embodiments, at least a portion of the first gate dielectric layer 130A1 can cover the two first source/drain regions 120A through other processes (for example, through the definition of a mask).

As shown in FIG. 1A, the first gate dielectric layer 130A1 and the first gate 140A are stacked on the substrate 100 along a first direction D1, and at least a portion of the first gate dielectric layer 130A1 overlaps the two first source/drain regions 120A in the first direction D1. The first direction D1 is, for example, parallel to a normal direction of an upper surface of the substrate 100. In the present embodiment, the first gate dielectric layer 130A1 is a multi-layered structure including a first layer 1321, a second layer 1341, a third layer 136 and a fourth layer 138. The first layer 1321, the second layer 1341, the third layer 136 and the fourth layer 138 are sequentially stacked on the substrate 100 along the first direction D1. The material of the first layer 1321 includes silicon oxynitride (SiON); the material of the second layer 1341 includes silicon nitride (SiN); the material of the third layer 136 includes oxide, and the material of the fourth layer 138 includes silicon nitride (SiN), which can be referred to as a multi-layered structure of O/N/O/N, but the present invention is not limited thereto. In other embodiments, the first gate dielectric layer 130A1 may be a multi-layered structure including a silicon oxynitride layer, a nitride layer, an oxide layer, a nitride layer and an oxide layer (O/N/O/N/O), a multi-layered structure including a silicon oxynitride layer, a nitride layer and a silicon oxynitride layer (O/N/O), or other suitable multi-layered structures.

According to the present embodiment, the layers of the first gate dielectric layer 130A1 that overlap the two first source/drain regions 120A in the first direction D1 are the first layer 1321 and the second layer 1341. However, the present invention is not limited thereto (detailed below). As long as the upper surfaces of the two first source/drain regions 120A can be covered by at least a portion of the first gate dielectric layer 130A1, it is within the scope of the present invention. The width W1 of the first layer 1321 and the second layer 1341 in the second direction D2 is greater than the width W2 of the first gate 140A, the third layer 136 and the fourth layer 138 in the second direction D2. There is a gap between the two first source/drain regions 120A in the second direction D2. The first gate 140A and the first gate dielectric layer 130A1 may extend along the third direction D3. The first direction D1, the second direction D2 and the third direction D3 may be perpendicular to each other.

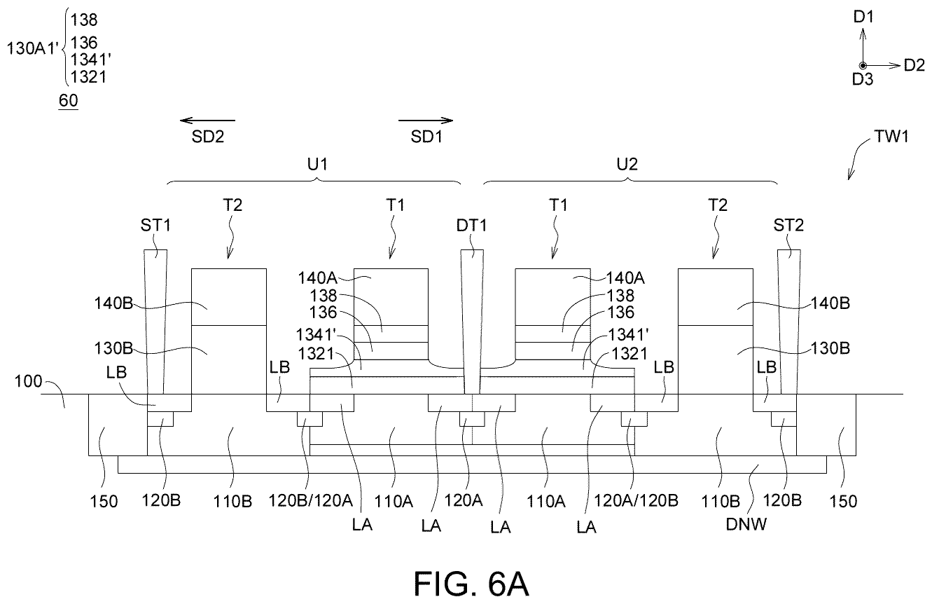

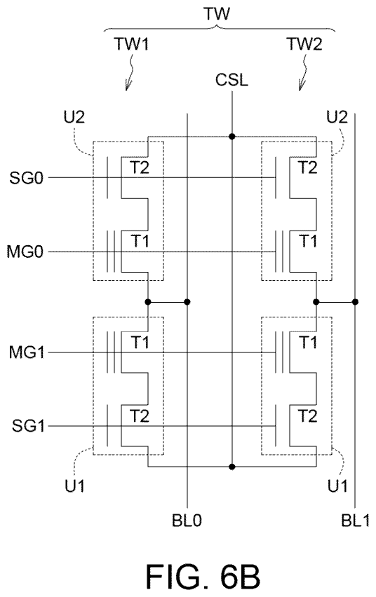

According to some embodiments, the substrate 100 may include more wells or doped regions (such as the lightly doped regions LA and LB, the third well 150 and the deep well DNW shown in FIG. 6A), which are omitted in FIG. 1A.

FIG. 1B is a schematic diagram of a semiconductor device 10C according to a comparative example of the present invention. The difference between the semiconductor device 10C and the semiconductor device 10 is that the first gate dielectric layer 130AC is different from the first gate dielectric layer 130A1, and other identical or similar parts will not be described in detail.

Referring to FIG. 1B, the difference between the first gate dielectric layer 130AC and the first gate dielectric layer 130A1 is that the first layer 132 and the second layer 134 of the first gate dielectric layer 130AC do not cover the two first source/drain regions 120A. That is, the first layer 132 and the second layer 134 do not overlap the two first source/drain regions 120A in the first direction D1. The materials of the first layer 132 and the second layer 134 are the same as the materials of the first layer 1321 and the second layer 1341, respectively.

According to some embodiments, the manufacturing process of the semiconductor devices 10 and 10C may include sequential steps S1 to S13 (not shown). In step S1, a first precursor layer (not shown) of the first layer 132 or 1321 is formed on the substrate 100 through a deposition process. In step S3, a second precursor layer (not shown) of the second layer 134 or 1341 is formed on the first precursor layer (not shown) through a deposition process. In step S5, a third precursor layer (not shown) of the third layer 136 is formed on the second precursor layer (not shown) through a deposition process. In step S7, a fourth precursor layer (not shown) of the fourth layer 138 is formed on the third precursor layer (not shown) through a deposition process. The first to fourth precursor layers (not shown) all extend above the two first source/drain regions 120A. In step S9, a first gate precursor layer (not shown) of the first gate 140A is formed on the fourth precursor layer (not shown) through a deposition process. In step S11, excessive portions of the first gate precursor layer are removed through an etching process, and the remaining portion of the first gate precursor layer forms the first gate 140A. During the etching process to the first gate precursor layer, portions of the third precursor layer (not shown) and the fourth precursor layer (not shown) may be removed simultaneously, so that the remaining portions of the third precursor layer and the fourth precursor layer form the third layer 136 and the fourth layer 138, respectively. In step S13, a conformal oxide film (not shown) is formed on the structure formed in step S11 through a re-oxidation process. After this step is completed, the resulting structure of the semiconductor device may be similar to the structure of the semiconductor device 10 in FIG. 1A.

As shown in FIG. 1B, after step S13, the excessive portions of the first precursor layer (not shown) and the second precursor layer (not shown) are removed through an etching process NHC, and the remaining portions of the first precursor layer and second precursor layer form the first layer 132 and the second layer 134, respectively. The etching process NHC causes the first gate dielectric layer 130AC to not cover the two first source/drain regions 120A.

As shown in FIG. 1A, the semiconductor device 10 does not perform the etching process NHC after step S13. The first precursor layer and the second precursor layer extending above the two first source/drain regions 120A form a first layer 1321 and a second layer 1341, respectively, and the first layer 1321 and the second layer 1341 cover the two first source/drain regions 120A.

During the etching process NHC, damage may be caused to the sidewalls of the first gate dielectric layer 130A1 or 130AC. Since the semiconductor device 10 does not need to go through the etching process NHC, chemical damage caused by the etchant can be reduced. The first gate dielectric layer 130A1 has better structural characteristics than the first gate dielectric layer 130AC.

FIG. 1C shows a schematic diagram of the semiconductor device 10C of FIG. 1B performing programming. FIG. 1D is a schematic diagram of the semiconductor device 10C of FIG. 1B performing erasing.

Please refer to FIG. 1C. During the programming process, electrons EL are injected into the second layer 134 of the first gate dielectric layer 130AC from the substrate 100, as shown by the arrows AR1.

Please refer to FIG. 1D. During the erasing process, holes HL are injected into the second layer 134 of the first gate dielectric layer 130AC from the substrate 100, as shown by arrows AR3.

During the programming or erasing process, damage may be caused to the first gate dielectric layer 130AC, especially the erasing operation. Since the mass of the hole HL is greater than the mass of the electron EL, the damage caused by the injection of the holes HL is greater than the damage caused by the injection of the electrons EL. As the number of program/erase cycling (P/E cycling) operations increases, the damage of the holes HL to the first gate dielectric layer 130AC becomes more obvious.

Please refer to Table 1 below, which shows the results of the simulated operations of the semiconductor device 10 and the semiconductor device 10C. After 100,000 program/erase cycles, the critical voltage change of the erase operation (ΔVtₑᵣₛ) of the semiconductor device 10C has reached 0.8V, and the read voltage of OV can no longer distinguish between the states of 0 and 1. At this time, the semiconductor device 10C has failed. On the contrary, the critical voltage change of the erase operation of the semiconductor device 10 is only 0.2V, and the read voltage of OV can still distinguish the states of 0 and 1. The semiconductor device 10 will fail after 1,000,000 program/erase cycles. Moreover, it can be seen from the transconductance (Gm) results that the transconductance of the semiconductor device 10C after the first program/erase cycle is 21 μA/V, and the transconductance after the 100,000th program/erase cycle becomes 9 μA/V, that is, the transconductance degradation (Gm degradation) is 12 μA/V (i.e., 21−9=12). The transconductance of the semiconductor device 10 after the first program/erase cycle is 21 μA/V, and the transconductance after the 100,000th program/erase cycle becomes 15 μA/V, that is, the transconductance degradation is 6 μA/V (i.e., 21−15=6), which is significantly improved compared to the semiconductor device 10C.

TABLE 1

| | critical voltage | |
|---|---|---|
| | change of the | transconductance |
| | erase operation | (Gm) |
| | (ΔVtₑᵣₛ) | degradation |
| semiconductor device 10C | 0.8 V | 12 μA/V |
| semiconductor device 10 | 0.2 V | 6 μA/V |

It can be seen that compared with the semiconductor device 10C, since at least a portion of the first gate dielectric layer 130A1 in the semiconductor device 10 covers the two first source/drain regions 120A (that is, the first layer 1321 and the second layer 1341 cover the two first source/drain regions 120A), the damage caused by the program/erase cycles to the first gate dielectric layer 130AC is greater than the damage caused by the program/erase cycles to the first gate dielectric layer 130A1, the semiconductor device 10 can perform more program/erase cycles and has better endurance.

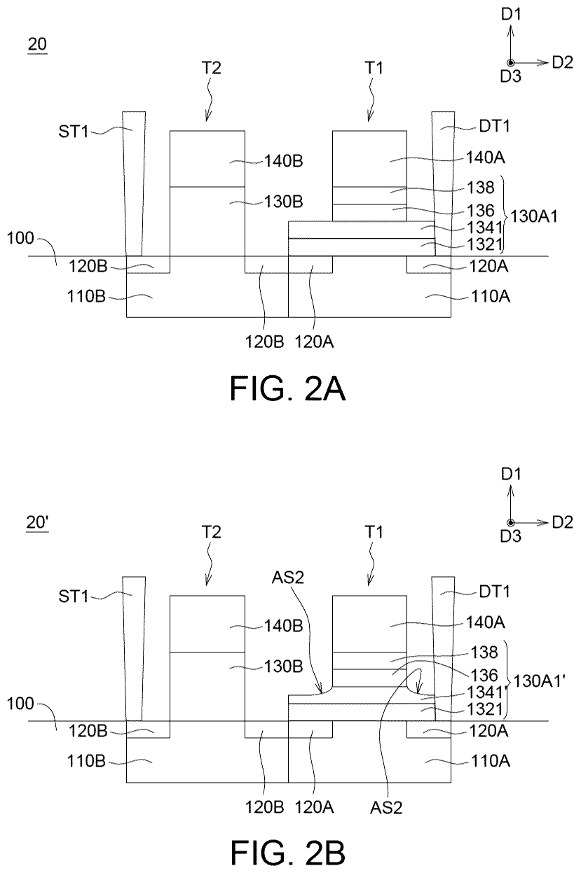

FIG. 2A is a schematic diagram of a semiconductor device 20 according to an embodiment of the present invention.

In the semiconductor device 10 of FIG. 1A, the first well 110A, the two first source/drain regions 120A, the first gate dielectric layer 130A1 and the first gate 140A correspond to a first transistor T1. The difference between the semiconductor device 20 and the semiconductor device 10 is that the semiconductor device 20 further includes a second transistor T2 in addition to the first transistor T1.

Referring to FIG. 2A, the semiconductor device 20 further includes a second well 110B, two second source/drain regions 120B, a second gate dielectric layer 130B and a second gate 140B. The second well 110B, the two second source/drain regions 120B, the second gate dielectric layer 130B and the second gate 140B correspond to the second transistor T2. The second well 110B is disposed on the substrate 100 and adjacent to the first well 110A. The two second source/drain regions 120B are disposed in the second well 110B and are separated from each other. The second gate dielectric layer 130B is disposed on the substrate 100. The second gate 140B is disposed on the second gate dielectric layer 130B, wherein the second gate dielectric layer 130B does not cover the two second source/drain regions 120B, but exposes the upper surfaces of the two second source/drain regions 120B. That is, the second gate dielectric layer 130B does not overlap the two second source/drain regions 120B in the second direction D2.

According to some embodiments, the doping concentration of the first well 110A is different from the doping concentration of the second well 110B. In the present embodiment, the doping concentration of the first well 110A is smaller than the doping concentration of the second well 110B, but the invention is not limited thereto. The threshold voltage of the first gate 140A can be adjusted by adjusting the doping concentration of the first well 110A.

According to some embodiments, the first well 110A and the second well 110B have a first conductivity type, the two first source/drain regions 120A and the two second source/drain regions 120B have a second conductivity type, and the first conductivity type is different from the second conductivity type. The first conductivity type is, for example, P type, and the second conductivity type is, for example, N type.

According to some embodiments, adjacent first source/drain region 120A and the second source/drain region 120B among the two first source/drain regions 120A and the two second source/drain regions 120B are connected to each other.

According to some embodiments, the semiconductor device 20 further includes a drain contact DT1 and a source contact ST1, wherein the drain contact DT1 is disposed on the first source/drain region 120A of the two first source/drain regions 120A that is farther away from the second well 110B, and the source contact ST1 is disposed on the second source/drain region 120 of the two second source/drain regions 110B that is farther away from the first well 110A.

According to some embodiments, at least a portion of the first gate dielectric layer 130A1 is adjacent to an in contact with the drain contact DT1; the second gate dielectric layer 130B and the source contact ST1 are separated from each other. For example, there is a gap in the second direction D2 between the second gate dielectric layer 130B and the source contact ST1.

FIG. 2B illustrates a schematic diagram of a semiconductor device 20′ according to a further embodiment of the present invention. The difference between the semiconductor device 20′ in FIG. 2B and the semiconductor device 20 in FIG. 2A is that the appearance of the first gate dielectric layer 130A1′ is different from the appearance of the first gate dielectric layer 130A1. Other identical or similar parts will not be described in detail.

Referring to FIG. 2B, the appearance of the first gate dielectric layer 130A1′ includes an arc-shaped profile AS2. In detail, the first gate dielectric layer 130A1′ has a main part, and both sides of the main part extend to form wing parts, wherein an upper side of each of the wing parts has an arc-shaped profile AS2, and the arc-shaped profile AS2 extends outward from the main part. In the present embodiment, both sides of the second layer 1341′ in the first gate dielectric layer 130A1′ include arc-shaped profiles AS2. The material of the second layer 1341′ is the same as the material of the first layer 1341. Other identical or similar parts will not be described in detail.

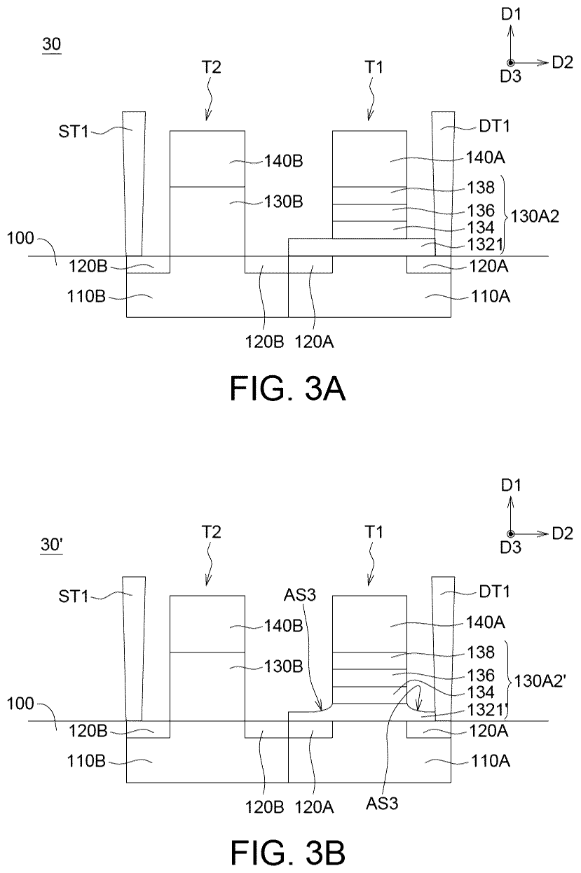

FIG. 3A is a schematic diagram of a semiconductor device 30 according to an embodiment of the present invention. The difference between the semiconductor device 30 and the semiconductor device 20 is that the first gate dielectric layer 130A2 is different from the first gate dielectric layer 130A1, and other identical or similar parts will not be described in detail.

Please refer to FIGS. 2A and 3A. The difference between the first gate dielectric layer 130A2 and the first gate dielectric layer 130A1 is that the second layer 134 does not cover the two first source/drain regions 120A. The material of the second layer 134 is the same as the material of the second layer 1341. Other identical or similar parts will not be described in detail. In other words, as shown in FIG. 3A, the width of the second layer 134 in the second direction D2 is smaller than the width of the first layer 1321 in the second direction D2, so that the second layer 134 does not overlap the two first source/drain regions 120A in the first direction D1, and the first layer 1321 still overlaps the two first source/drain regions 120A in the first direction D1.

FIG. 3B illustrates a schematic diagram of a semiconductor device 30′ according to a further embodiment of the present invention. The difference between the semiconductor device 30′ in FIG. 3B and the semiconductor device 30 in FIG. 3A is that the appearance of the first gate dielectric layer 130A2′ is different from the appearance of the first gate dielectric layer 130A2. Other identical or similar parts will not be described in detail.

Please refer to FIG. 3B. The appearance of the first gate dielectric layer 130A2′ includes an arc-shaped profile AS3. In detail, the first gate dielectric layer 130A2′ has a main part, and both sides of the main part extend to form wing parts, wherein an upper side of each of the wing parts has an arc-shaped profile AS3, and the arc-shaped profile AS3 extends outward from the main part. In the present embodiment, both sides of the first layer 1321′ in the first gate dielectric layer 130A2′ include arc-shaped profiles AS3. The material of the first layer 1321′ is the same as the material of the first layer 1321. Other identical or similar parts will not be described in detail.

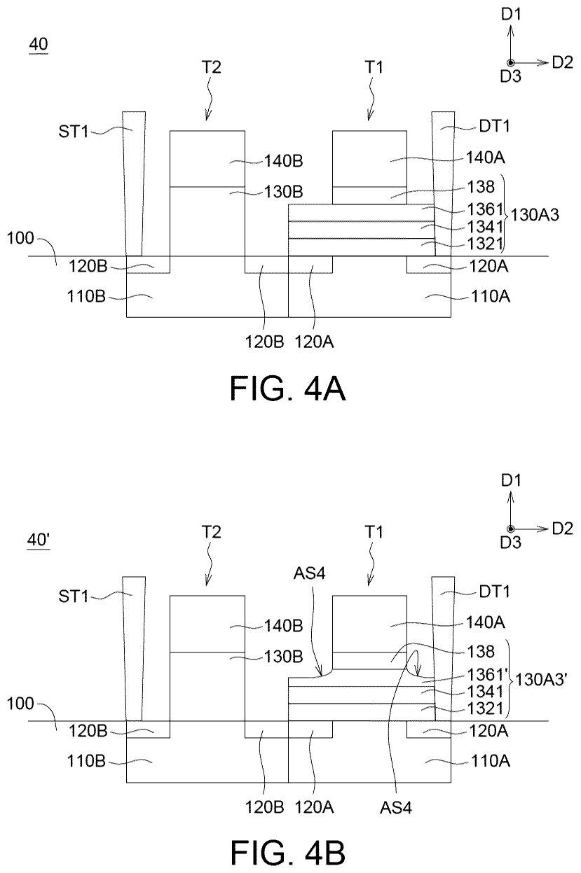

FIG. 4A is a schematic diagram of a semiconductor device 40 according to an embodiment of the present invention. The difference between the semiconductor device 40 and the semiconductor device 20 is that the first gate dielectric layer 130A3 is different from the first gate dielectric layer 130A1, and other identical or similar parts will not be described in detail.

Please refer to FIGS. 2A and 4A. The difference between the first gate dielectric layer 130A3 and the first gate dielectric layer 130A1 is that the third layer 1361 also covers the two first source/drain regions 120A. The material of the third layer 1361 is the same as the material of the third layer 136. Other identical or similar parts will not be described in detail. In other words, as shown in FIG. 4A, the width of the third layer 1361 in the second direction D2 is equal to the width of the first layer 1321 and the second layer 1341 in the second direction D2, and is smaller than the width of the fourth layer 138 and the first gate 140A in the second direction D2, so that the third layer 1361 overlaps the two first source/drain regions 120A in the first direction D1.

FIG. 4B is a schematic diagram of a semiconductor device 40′ according to a further embodiment of the present invention. The difference between the semiconductor device 40′ in FIG. 4B and the semiconductor device 40 in FIG. 4A is that the appearance of the first gate dielectric layer 130A3′ is different from the appearance of the first gate dielectric layer 130A3. Other identical or similar parts will not be described in detail.

Please refer to FIG. 4B. The appearance of the first gate dielectric layer 130A3′ includes an arc-shaped profile AS4. In detail, the first gate dielectric layer 130A3′ has a main part, and both sides of the main part extend to form wing parts, wherein an upper side of each of the wing parts has an arc-shaped profile AS4, and the arc-shaped profile AS4 extends outward from the main part. In the present embodiment, both sides of the third layer 1361′ in the first gate dielectric layer 130A3′ include arc-shaped profiles AS4. The material of the third layer 1361′ is the same as the material of the third layer 1361. Other identical or similar parts will not be described in detail.

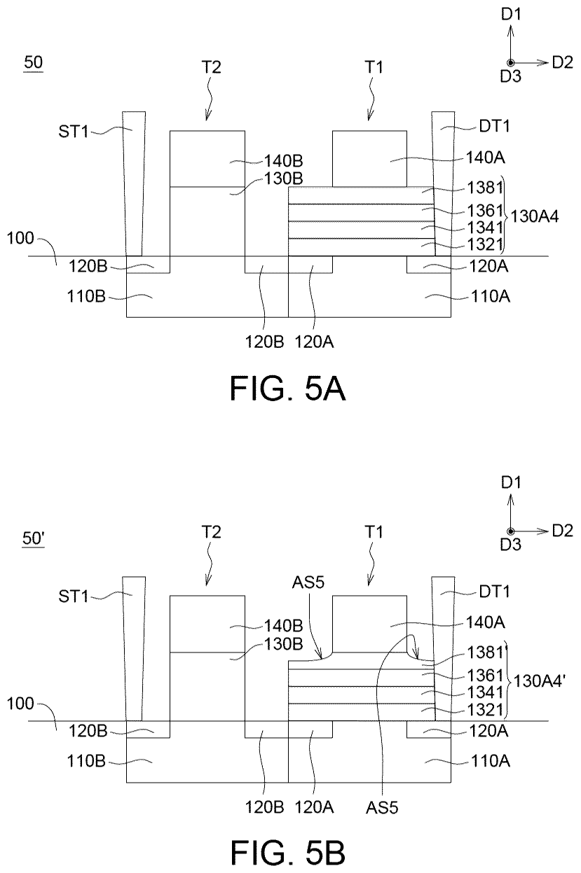

FIG. 5A is a schematic diagram of a semiconductor device 50 according to an embodiment of the present invention. The difference between the semiconductor device 50 and the semiconductor device 20 is that the first gate dielectric layer 130A4 is different from the first gate dielectric layer 130A1, and other identical or similar parts will not be described in detail.

Please refer to FIGS. 2A and 5A. The difference between the first gate dielectric layer 130A4 and the first gate dielectric layer 130A1 is that the third layer 1361 to the fourth layer 1381 also cover the two first source/drain regions 120A. The materials of the third layer 1361 and the fourth layer 1381 are the same as the materials of the third layer 136 and the fourth layer 138, respectively. Other identical or similar parts will not be described in detail. In other words, as shown in FIG. 5A, the widths of the first layer 1321 to the fourth layer 1341 in the second direction D2 are the same as each other and are larger than the width of the first gate 140A in the second direction D2, so that the first layer 1321 to the fourth layer 1341 overlap the two first source/drain regions 120A in the first direction D1.

FIG. 5B is a schematic diagram of a semiconductor device 50′ according to a further embodiment of the present invention. The difference between the semiconductor device 50′ in FIG. 5B and the semiconductor device 50 in FIG. 5A is that the appearance of the first gate dielectric layer 130A4′ is different from the appearance of the first gate dielectric layer 130A4. Other identical or similar parts will not be described in detail.

Please refer to FIG. 5B. The appearance of the first gate dielectric layer 130A4′ includes an arc-shaped profile AS5. In detail, the first gate dielectric layer 130A4′ has a main part, and both sides of the main part extend to form wing parts, wherein an upper side of each of the wing parts has an arc-shaped profile AS5, and the arc-shaped profile AS5 extends outward from the main part. In the present embodiment, both sides of the fourth layer 1381′ in the first gate dielectric layer 130A4′ include arc-shaped profiles AS5. The material of the fourth layer 1381′ is the same as the material of the fourth layer 1381. Other identical or similar parts will not be described in detail.

FIG. 6A is a partial cross-sectional view of a semiconductor device 60 according to an embodiment of the present invention. FIG. 6B shows an equivalent circuit diagram of the semiconductor device 60 of FIG. 6A.

Referring to FIGS. 6A and 6B, the semiconductor device 60 includes at least one transistor row TW. In some embodiments, an amount of the transistor row TW is plural, and the plurality of transistor rows TW form a transistor array. For example, FIG. 6B shows that at least one transistor row TW includes two transistor rows TW1 and TW2, but the number of transistor rows of the present invention is not limited thereto. The transistor row TW1 is composed of a first combination unit U1 and a second combination unit U2.

The structure of the transistor row TW2 is the same as the structure of the transistor row TW1, and is also composed of a combination of the first combination unit U1 and the second combination unit U2. In the present embodiment, each of the transistor rows TW is composed of a first combination unit U1 and a second combination unit U2. However, the invention is not limited thereto. In other embodiments, each of the transistor rows TW may be composed of a plurality of first combination units U1 and a plurality of second combination units U2.

Each of the transistor rows TW includes a first side SD1 and a second side SD2. The second side SD2 is relative to the first side SD1. The first side SD1 and the second side SD2 correspond to the right side and the left side respectively, for example. The first combination unit U1 includes a first transistor T1 adjacent to the first side SD1 and a second transistor T2 adjacent to the second side SD2. The second combination unit U2 includes a first transistor T1 adjacent to the second side SD2 and a second transistor T2 adjacent to the first side SD1. As shown in FIG. 6A, the structure of the first gate dielectric layers 130A1′ corresponding to the first transistors T1 in the first combination unit U1 and the second combination unit U2 is the same as the structure of the first gate dielectric layer 130A1′ shown in FIG. 2B, with arc-shaped profiles AS2. However, the present invention is not limited thereto. The structure of the first gate dielectric layers 130A1′ corresponding to the first transistors T1 in the first combination unit U1 and the second combination unit U2 can be the structure of the first gate dielectric layers 130A1 to 130A4′ corresponding to the first transistor T1 as shown in FIGS. 2A to 5B, or other suitable structures.

The first transistor T1 of the first combination unit U1 and the first transistor T1 of the second combination unit U2 share a drain contact SD1. The second transistor T2 of the first combination unit U1 and the second transistor T2 of the second combination unit U2 are electrically connected to different source contacts ST1 and ST2, respectively.

According to some embodiments, the first combination unit U1 and the second combination unit U2 may be arranged in an alternating or repeated manner. For example, each of the transistor rows TW can be four repetitions of the first combination unit U1 and the second combination unit U2, that is, from the second side SD2 to the first side SD1, the sequence is the first combination unit U1—the second combination unit U2—the first combination unit U1—the second combination unit U2—the first combination unit U1—the second combination unit U2—the first combination unit U1—the second combination unit U2, but the invention is not limited thereto.

According to some embodiments, the substrate 100 further includes lightly doped regions LA and LB, a third well 150 and a deep well DNW. Two lightly doped regions LA are disposed in the first well 110A and are separated from each other, and the two lightly doped regions LA are respectively adjacent to the two first source/drain regions 120A. Two lightly doped regions LB are disposed in the second well 110B and are separated from each other, and the two lightly doped regions LB are respectively adjacent to the two second source/drain regions 120B. The third well 150 is adjacent to the second well 110B. The deep well DNW is provided under the first well 110A and the second well 110B.

According to some embodiments, the lightly doped regions LA and LB have a second conductivity type (e.g., N type), and the doping concentrations of the lightly doped regions LA and LB are respectively smaller than the doping concentrations of the first source/drain region 120A and the second source/drain region 120B. The third well 150 and the deep well DNW also have a second conductivity type (e.g., N-type).

As shown in FIGS. 6A and 6B, in each of the transistor rows TW1 and TW2, the first transistors T1 and the second transistors T2 in the first combination unit U1 and the second combination unit U2 are electrically connected to each other through the corresponding first source/drain regions 120A and the second source/drain regions 120B.

A first combination unit U1 and a second combination unit U2 in each of the transistor rows TW1 and TW2 can respectively serve as a memory cell. FIG. 6B is an exemplary 2×2 memory cell array, but the invention is not limited thereto. The first gate 140A in the first transistor T1 serves as a memory gate, and the second gate 140B in the second transistor T2 serves as a selective gate. The first combination unit U1 and a second combination unit U2 in the transistor row TW1 are electrically connected to the bit line BL0 through the shared drain contact DT1. The first combination unit U1 and a second combination unit U2 in the transistor row TW2 are electrically connected to the bit line BL1 through the shared drain contact DT1. The source contacts ST1 and ST2 in the transistor rows TW1 and TW2 are electrically connected to the common source line CSL. The first gate 140A of the first combination unit U1 in the transistor row TW1 is electrically connected to the first gate 140A of the first combination unit U1 in the transistor row TW2 (marked as word line MG1). The second gate 140B of the first combination unit U1 in the transistor row TW1 is electrically connected to the second gate 140B of the first combination unit U1 in the transistor row TW2 (marked as word line SG1). The first gate 140A of the second combination unit U2 in the transistor row TW1 is electrically connected to the second combination unit U2 in the transistor row TW2 (marked as word line MG0). The second gate 140B of the second combination unit U2 in the transistor row TW1 is electrically connected to the second gate 140B of the second combination unit U2 in the transistor row TW2 (marked as word line SG0).

During the operation of the semiconductor device 60, the memory cells (for example, four memory cells) corresponding to the first combination unit U1 and the second combination unit U2 of the transistor row TW1 and TW2 can be turned on or off by applying voltages to the bit lines BL0 to BL1, the common source line CSL, and the word lines SG0 to SG1 and MG0 to MG1. When the second combination unit U2 of the transistor row TW1 is a selected memory cell, the first combination unit U1 of the transistor row TW1 is a half-selected memory cell (selecting the corresponding word lines SG1 and MG1), the second combination unit U2 of the transistor row TW2 is a half-selected memory cell (selecting the corresponding bit line BL1), and the first combination unit U1 of the transistor row TW2 is an unselected memory cell.

Compared with the comparative example in which the memory cell has only a single transistor, since the memory cell of the semiconductor device of the present invention is a dual transistor (i.e., the first transistor T1 and the second transistor T2), the selective gate (second gate 140B) can control better, and the semiconductor device can have lower leakage current during operation of the memory cell and can have better reliability. The selective gate (second gate 140B) of the semiconductor device of the present invention can operate as a high voltage metal oxide semiconductor (HV MOS), but the present invention is not limited thereto.

In summary, the present invention provides a semiconductor device with improved endurance, in which at least a portion of the first gate dielectric layer covers the two first source/drain regions. According to an embodiment of the present invention, the sidewalls of the first gate dielectric layer of the semiconductor device are not easily damaged by chemicals used in the etching process or the cleaning process. Therefore, the first gate dielectric layer has good structural characteristics (not prone to have defects) and has good endurance in the operation of the memory. The service life of the semiconductor device can also be extended and costs can be reduced.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a first well disposed in the substrate;
two first source/drain regions disposed in the first well and separated from each other;
a first gate dielectric layer disposed on the substrate, wherein the first gate dielectric layer is a multi-layered structure; and
a first gate is disposed on the first gate dielectric layer, wherein at least one portion of the first gate dielectric layer covers the two first source/drain regions.

2. The semiconductor device according to claim 1, wherein the multi-layered structure comprises one or more nitride layers and one or more oxide layers.

3. The semiconductor device according to claim 1, wherein the first gate dielectric layer and the first gate are stacked on the substrate along a first direction, and the at least one portion of the first gate dielectric layer overlaps the two first source/drain regions in the first direction.

4. The semiconductor device according to claim 1, further comprising:
a second well disposed on the substrate and adjacent to the first well;
two second source/drain regions disposed in the second well and separated from each other;
a second gate dielectric layer disposed on the substrate; and
a second gate disposed on the second gate dielectric layer, wherein the second gate dielectric layer exposes upper surfaces of the two second source/drain regions.

5. The semiconductor device according to claim 4, wherein a doping concentration of the first well is different from a doping concentration of the second well.

6. The semiconductor device according to claim 4, wherein the first well and the second well have a first conductivity type, the two first source/drain regions and the two second source/drain regions have a second conductivity type, and the first conductivity type is different from the first conductivity type.

7. The semiconductor device according to claim 4, wherein adjacent first source/drain region and second source/drain region among the two first source/drain regions and the two second source/drain regions are connected to each other.

8. The semiconductor device according to claim 4, further comprising a drain contact and a source contact, wherein the drain contact is disposed on the first source/drain region of the two first source/drain regions that is farther away from the second well, and the source contact is disposed on the second source/drain region of the two second source/drain regions that is farther away from the first well.

9. The semiconductor device according to claim 8, wherein the at least a portion of the first gate dielectric layer is adjacent to the drain contact; the second gate dielectric layer and the source contact are separated from each other.

10. The semiconductor device according to claim 1, wherein the first gate dielectric layer has a main part, and both sides of the main part extend to form wing parts, wherein an upper side of each of the wing parts has an arc-shaped profile, and the arc-shaped profile extends outward from the main part.

11. The semiconductor device according to claim 5, wherein the first well, the two first source/drain regions, the first gate dielectric layer, and the first gate correspond to a first transistor, and the second well, the two second source/drain regions, the second gate dielectric layer, and the second gate correspond to a second transistor;
wherein the semiconductor device further comprises a transistor row, the transistor row is composed of a combination of a first combination unit and a second combination unit, the first combination unit comprises the first transistor adjacent to a first side and a second transistor adjacent to the second side, the second side is opposite to the first side; the second combination unit includes the first transistor adjacent to the second side and the second transistor adjacent to the first side.

12. The semiconductor device according to claim 11, wherein the first combination unit and the second combination unit are arranged in an alternating or repeated manner.

13. The semiconductor device according to claim 11, wherein an amount of the transistor row is plural, and the plurality of transistor rows form a transistor array.

14. The semiconductor device according to claim 11, wherein the first transistor of the first combination unit and the first transistor of the second combination unit share a drain contact, and the second transistor of the first combination unit and the second transistor of the second combination unit are electrically connected to different source contacts respectively.

15. A method of manufacturing a semiconductor device, including:
providing a substrate;
forming a first well disposed in the substrate;
forming two first source/drain regions disposed in the first well and separated from each other;
forming a first gate dielectric layer disposed on the substrate, wherein the first gate dielectric layer is a multi-layered structure; and
forming a first gate disposed on the first gate dielectric layer, wherein at least one portion of the first gate dielectric layer covers the two first source/drain regions.

16. The method according to claim 15, further comprising:
forming a second well disposed on the substrate and adjacent to the first well;
forming two second source/drain regions disposed in the second well and separated from each other;
forming a second gate dielectric layer disposed on the substrate; and
forming a second gate disposed on the second gate dielectric layer, wherein the second gate dielectric layer exposes upper surfaces of the two second source/drain regions.

17. The method according to claim 16, wherein the first well and the second well have a first conductivity type, the two first source/drain regions and the two second source/drain regions have a second conductivity type, and the second conductivity type is different from the first conductivity type.

18. The method according to claim 16, further comprising forming a drain contact and a source contact, wherein the drain contact is disposed on the first source/drain region of the two first source/drain regions that is farther away from the second well, and the source contact is disposed on the second source/drain region of the two second source/drain regions that is farther away from the first well.

19. The method according to claim 18, wherein the at least one portion of the first gate dielectric layer is adjacent to the drain contact; and the second gate dielectric layer and the source contact are separated from each other.

20. The method according to claim 16, wherein the first well, the two first source/drain regions, the first gate dielectric layer, and the first gate correspond to a first transistor, and the second well, the two second source/drain regions, the second gate dielectric layer, and the second gate correspond to a second transistor;
wherein the semiconductor device further comprises a transistor row, the transistor row is composed of a combination of a first combination unit and a second combination unit, the first combination unit comprises the first transistor adjacent to a first side and the second transistor adjacent to a second side, the second side is opposite to the first side; the second combination unit comprises the first transistor adjacent to the second side and the second transistor adjacent to the first side.
